(19) United States
(12) Patent Application Publication
(10) Pub. No.: US 2014/0239976 A1
(43) Pub. Date: Aug. 28, 2014

(54) AUXILIARY TEST APPARATUS FOR ELECTROMAGNETIC COMPATIBILITY AND TEST METHOD USING THE SAME

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventors: JIAN-WEI LUO, Shenzhen (CN); CHUN-CHIEH TSEN, New Taipei (TW)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/949,416

(22) Filed: Jul. 24, 2013

(30) Foreign Application Priority Data
Feb. 27, 2013 (CN) 2013100637994

(51) Int. Cl. G01R 29/08

(52) U.S. Cl. CPC G01R 29/0814
USPC 324/602

(57) ABSTRACT

An auxiliary test apparatus for electromagnetic compatibility includes two substantially parallel side plates and a dividing plate substantially perpendicularly connected between centerlines of the side plates. A through hole is defined in a center portion of the dividing plate. Top and bottom surfaces of the dividing plate and the inner surfaces of the side plates are covered by conductive foam.

### BACKGROUND

1. Technical Field

The present disclosure relates to a test apparatus for electromagnetic compatibility and a test method using the test apparatus.

2. Description of Related Art

Electromagnetic compatibility (EMC) is the study of the unintentional generation and reception of electromagnetic energy and its relationship to electronic devices and systems. The primary goal of EMC testing is to identify the sources of electromagnetic energy emitted from an electronic device in an effort to reduce potential interference to other equipment, as well as determine the susceptibility of the equipment from electromagnetic energy emitted from other electronic devices nearby. Electromagnetic compatibility of consumer electronic products must be tested before sale. When testing an uncovered server, an auxiliary server will be set on the first server to make a simulation of real use environment in a server rack. However, the second server is difficult to align with the uncovered first server.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an assembled view of an embodiment of an auxiliary test apparatus for testing electromagnetic compatibility.

FIG. 2 and FIG. 3 show different states of use of the auxiliary test apparatus of FIG. 1.

FIG. 4 is a flowchart of an embodiment of a method for testing a server for electromagnetic compatibility.

### DETAILED DESCRIPTION

The present disclosure, including the accompanying drawings, is illustrated by way of examples and not by way of limitation. It should be noted that references to “an” or “one” embodiment in this disclosure are not necessarily to the same embodiment, and such references mean “at least one.”

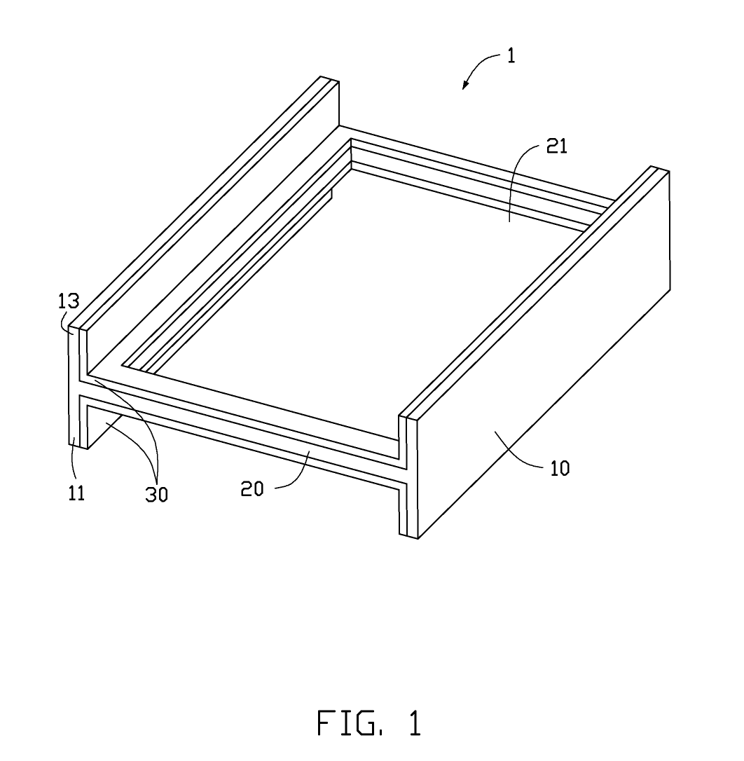

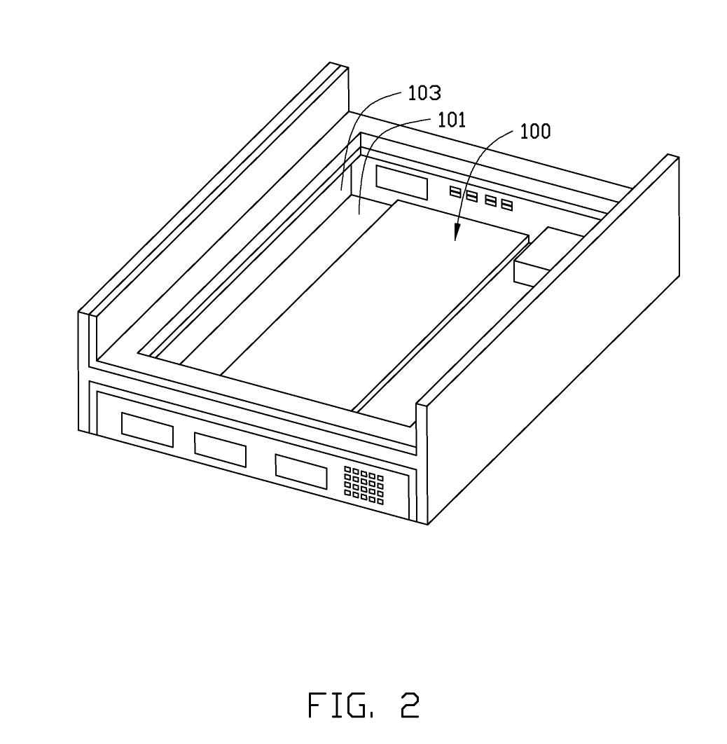

Referring to FIGS. 1 and 2, an embodiment of an auxiliary test apparatus 1 is used for testing electromagnetic compatibility of a main server 100. The auxiliary test apparatus 1 has a substantially H-shaped cross-section and includes two substantially parallel side plates 10 and a dividing plate 20 substantially perpendicularly connected between centerlines of the side plates 10. The dividing plate 20 defines a through hole 21 in a center. Each side plate 10 is divided into a lower portion 11 below the dividing plate 20 and an upper portion 13 above the dividing plate 20. An amount of conductive foam 30 is attached to inner surfaces of the side plates 10 and top and bottom surfaces of the dividing plate 20.

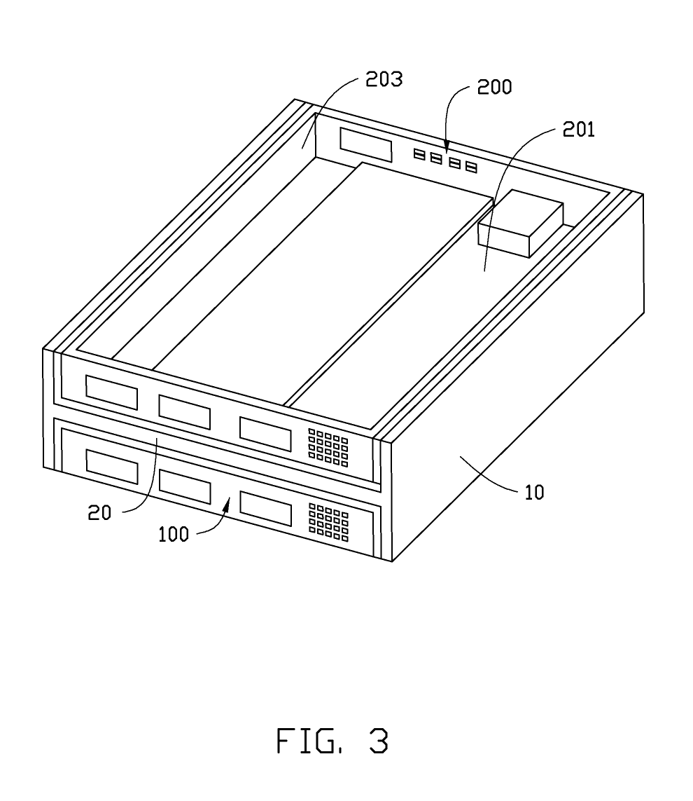

Referring to FIGS. 2 and 3, the auxiliary test apparatus 1 can be sandwiched between the main server 100 and an auxiliary server 200. The main server 100 is without an upper cover, and includes a bottom wall 101 and four sidewalls 103 extending up from four sides of the bottom wall 101. The auxiliary server 200 is similar to the main server 100, and includes a bottom wall 201 and four sidewalls 203.

When the main server 100 is to be tested, the auxiliary test apparatus 1 is set on the main server 100. The lower portions 11 of the side plates 10 sandwich the main server 100. The dividing plate 20 is supported on tops of the sidewalls 103. The auxiliary server 200 is set on the dividing plate 20. The upper portions of the side plates 10 sandwich the auxiliary server 200. The bottom wall 201 shields the through hole 21. Thus, the electromagnetic compatibility of the main server 100 can be tested.

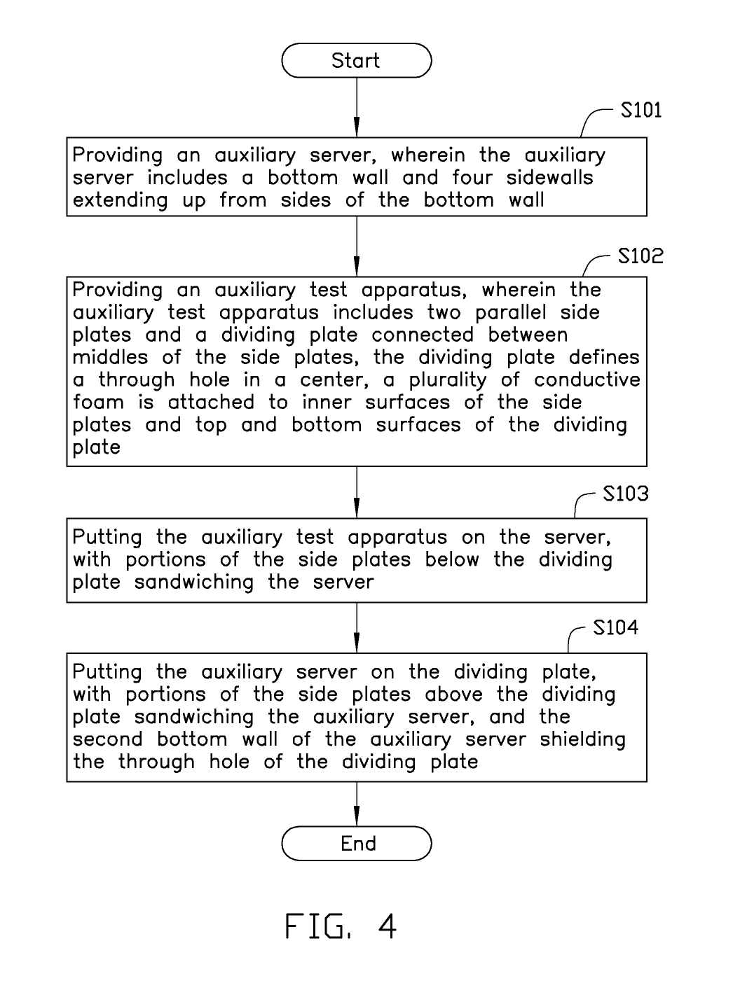

Referring to FIG. 4, an embodiment of a test method for testing electromagnetic compatibility of the main server 100 includes the following steps.

In step S101, an auxiliary server 200 is provided, wherein the auxiliary server 200 includes a bottom wall 201 and four sidewalls 203 extending up from sides of the bottom wall 201.

In step S102, an auxiliary test apparatus 1 is provided, wherein the auxiliary test apparatus 1 includes two substantially parallel side plates 10 and a dividing plate 20 connected between the centerlines of the side plates 10, the dividing plate 20 defines a through hole 21 in a center portion, and an amount of conductive foam 30 is attached to inner surfaces of the side plates 10 and top and bottom surfaces of the dividing plate 20.

In step S103, the auxiliary test apparatus 1 is put on the main server 100, with portions of the side plates 10 below the dividing plate 20 sandwiching the main server 100.

In step S104, the auxiliary server 200 is put on the dividing plate 20, with portions of the side plates 10 above the dividing plate 20 sandwiching the auxiliary server 200, and the bottom wall 201 of the auxiliary server 200 covering and shielding the through hole 21 of the dividing plate 20.

In the embodiment, the auxiliary test apparatus 1 aligns the auxiliary server 200 with the main server 100 automatically and conveniently.

It is to be understood, however, that even though numerous characteristics and advantages of the embodiments have been set forth in the foregoing description, together with details of the structure and function of the embodiments, the present disclosure is illustrative only, and changes may be made in details, especially in the matters of shape, size, and arrangement of parts within the principles of the embodiments to the full extent indicated by the broad general meaning of the terms in which the appended claims are expressed.

What is claimed is:

1. An auxiliary test apparatus for electromagnetic compatibility, comprising two substantially parallel side plates and a dividing plate connected between centerlines of the side plates, wherein the dividing plate defines a through hole in a center portion, and a plurality of conductive foam is attached to inner surfaces of the side plates and top and bottom surfaces of the dividing plate.

2. An auxiliary test method for testing electromagnetic compatibility of a main server without an upper cover, the main server comprising a first bottom wall and four first sidewalls extending up from sides of the first bottom wall, the method comprising:
providing an auxiliary server, wherein the auxiliary server comprises a second bottom wall and four second sidewalls extending up from sides of the second bottom wall;
providing an auxiliary test apparatus, wherein the auxiliary test apparatus comprises two substantially parallel side plates and a dividing plate connected between centerlines of the side plates, the dividing plate defines a through hole in a center portion, and a plurality of conductive foam is attached to inner surfaces of the side plates and top and bottom surfaces of the dividing plate;
putting the auxiliary test apparatus on the main server, with portions of the side plates below the dividing plate sandwiching the main server; and
putting the auxiliary server on the dividing plate, with portions of the side plates above the dividing plate sandwiching the auxiliary server, and the second bottom wall of the auxiliary server shielding the through hole of the dividing plate.
